(19) United States
(12) Patent Application Publication
(10) Pub. No.: US 2007/0089784 A1
(43) Pub. Date: Apr. 26, 2007

(54) Solar cell-driven display device and method of manufacturing thereof

(76) Inventors: Chang Ho Noh, Suwon-Si (KR); Sung Hen Cho, Seoul (KR); Ki Yong Song, Seoul (KR); Jin Young Kim, Suwon-Si (KR); Jong Min Kim, Suwon-Si (KR)

Correspondence Address: CANTOR COLBURN, LLP, 55 GRIFFIN ROAD SOUTH, BLOOMFIELD, CT, 06002, US

(21) Appl. No.: 11/447,245

(22) Filed: Jun. 5, 2006

(30) Foreign Application Priority Data
Oct. 26, 2005 (KR) 2005-101357

(51) Int. Cl. H01L 31/00; G09G 3/06

(52) U.S. Cl. 136/263; 345/44

(57) ABSTRACT

Disclosed herein are a solar cell-driven display device wherein a dye-sensitized solar cell, which comprises a light-absorbing layer that comprises a semiconductor electrode including a transparent electrode formed on a substrate and nanocrystals adsorbed with a photosensitive dye on the transparent electrode, and a hole transport layer and a counter electrode, is formed so as to exhibit a display device function using a quantum dot light-emitting layer, as well as a manufacturing method thereof. The solar cell-driven display device exhibits the display device function using only solar light, without needing a separate power supply device, and thus can be applied to advertising displays in isolated areas or as other outdoor advertising displays.

### BACKGROUND OF THE INVENTION

This non-provisional application claims priority under 35 U.S.C. § 119(a) to Korean Patent Application No. 2005-101357 filed on Oct. 26, 2005, the entire contents of which are hereby incorporated by reference.

1. Field of the Invention

The present invention relates to a solar cell-driven display device and a method of manufacturing thereof. More particularly, the present invention relates to a solar cell-driven display device comprising a transparent electrode formed on a substrate, a light-absorbing layer formed on the transparent electrode, a hole transport layer, and a counter electrode. A quantum dot light-emitting layer is formed on the surface of the light-absorbing layer.

2. Description of the Prior Art

Various display devices have recently been developed for outdoor advertising displays and the like. Such advertising displays are often placed on the roofs of buildings and the like. They are also sometimes installed in isolated areas where it is impossible to easily replace the cells of the displays or to connect electric power supply lines to the displays. For this reason, the development of displays that use self-generated electric power are actively being investigated.

For example, display devices that receive electric power from solar cells attached to the back surface thereof have been suggested. However, such display devices have a problem in that their volume greatly increases, because a solar cell panel and a display device panel, which have been separately manufactured, are generally assembled with each other. Another problem is that their manufacturing process is complex and hence is expensive, due to the presence of circuits and interconnects between the solar cell and the display device.

U.S. Pat. No. 6,104,372 discloses a solar cell-driven display wherein a display device comprising at least one electrochromic cell, at least one photo-electrochemical cell, a solar cell, and a battery are formed integrally with each other. In this display device, the display portion contains a lithium electrolyte, so that it turns blue when the battery is charged and white when the battery is discharged.

Meanwhile, Japanese Patent Laid-Open Publication No. 2004-93602 discloses a solar cell-attached display device comprising: a transmission-type solar cell; a light-emitting element disposed on the transmission-type solar cell; a light guide plate disposed on the transmission-type solar cell and serving to guide light emitted from the light-emitting element to the outside; and a transmission-type liquid crystal panel disposed on the light guide plate. However, the disclosed display device has problems in that the light guide plate is required as a separate element and circuits and interconnects for connecting the separate element to the light-emitting element and the display element are complex, thereby increasing manufacturing costs and complicating the manufacturing process.

Korean Patent Publication Laid-Open Publication No. 2005-83243 discloses a solar cell-integrated display device comprising: a self-light-emitting display section comprising a first transparent substrate, a first transparent electrode deposited on the first transparent substrate, a second transparent electrode corresponding to the first transparent electrode, and a self-light-emitting layer between the first transparent electrode and the second transparent electrode; a polymer film applied on the second transparent electrode and containing carbon nanotubes for improving the flow of electrons; and a solar cell section bonded on the polymer film and serving to supply electric power. However, this solar cell-integrated display device also has problems in that the existing display element has a complex structure that is physically connected, and separate elements such as the polymer film and a multi-layer insulating film are additionally formed, thus making the manufacturing process relatively complex.

### SUMMARY OF THE INVENTION

Accordingly, the present invention provides a display device, which is driven only by solar light without needing a separate electric power source or a secondary cell, as well as a manufacturing method thereof.

The present invention further provides a solar cell-driven display device that functions both as a display device and as a light-emitting device and is manufactured using a simpler process.

The present invention provides a solar cell-driven display device that comprises a dye-sensitized solar cell having a semiconductor electrode. The semiconductor electrode comprises a transparent electrode formed on a substrate with nanocrystals formed on the transparent electrode and adsorbed with a photosensitive dye. The dye-sensitized solar cell also comprises a hole transport layer and a counter electrode, and is formed so as to exhibit a display device function using a quantum dot light-emitting layer.

The solar cell-driven display device according to the present invention comprises: a dye-sensitized solar cell comprising a semiconductor electrode that comprises a transparent electrode made of a conductive material coated on a substrate with nanocrystals formed on the transparent electrode. The nanocrystals are adsorbed with a photosensitive dye. The dye-sensitized solar cell also comprises a hole transport layer, a counter electrode; and a quantum dot light-emitting layer.

The average particle size of quantum dots in the quantum dot light-emitting layer is in a range of about 1 to about 5 nanometers (nm). The quantum dots can be screened into particle size fractions for the multicolor display. The particle size of the quantum dots is controlled according to light-emitting colors. For example, the average particle size of quantum dots for blue displays is in a range of about 1.1 to about 1.5 nm, while the average particle size of quantum dots for green displays is in a range of about 2.1 to about 2.5 nm, and the average particle size of quantum dots for red display is in a range of about 2.6 to about 3.0 nm.

In another aspect, the present invention provides a method of manufacturing a solar cell-driven display device comprising a dye-sensitized solar cell. The dye-sensitized solar cell comprises a quantum dot light-emitting layer formed on a nanocrystalline metal oxide semiconductor material in a desired display pattern, whereby the solar cell-driven display device shows display characteristics using solar radiation.

The inventive method for manufacturing the solar cell-driven display device comprises: forming on a transparent electrode, a layer comprising a nanocrystalline semiconductor material and a dye molecule adsorbed on a portion of the nanocrystalline material; adsorbing a quantum dot light-emitting material onto a portion of the surface of the nanocrystalline semiconductor material according to patterns to be displayed, thus forming a quantum dot light-emitting layer; forming a hole transport layer on the nanocrystalline semiconductor layer on which the dye and the quantum dot light-emitting layer have been adsorbed; and forming a counter electrode on the hole transport layer.

### BRIEF DESCRIPTION OF THE DRAWINGS

The above and other features and advantages of the present invention will be more clearly understood from the following detailed description taken in conjunction with the accompanying drawings, in which:

FIG. 1a is a schematic cross-sectional view of a solar cell-driven display device according to one embodiment of the present invention;

FIG. 1b is a schematic cross-sectional view of a solar cell-driven display device according to an embodiment in which solar cells divided into small units are connected in series with each other; and

FIG. 2 is a schematic diagram showing a state where a quantum dot having a core-shell alloy structure has been linked to the surface of metal oxide.

### DETAILED DESCRIPTION OF THE INVENTION

This invention will now be described in further detail with reference to the accompanying drawings.

A solar cell-driven display device according to the present invention comprises a light-absorbing layer comprising a semiconductor electrode comprising a transparent electrode formed on a substrate with nanocrystals formed on the transparent electrode. The nanocrystals have adsorbed onto them a photosensitive dye. The solar cell also comprises a hole transport layer and a counter electrode and a quantum dot light-emitting layer formed on the surfaces of nanocrystals of the light-absorbing layer.

The solar cell-driven display device is characterized in that a photosensitive dye, which is used in manufacturing a dye-sensitized solar cell, is formed in combination with a quantum dot for forming a light-emitting display device, on the metal oxide nanoparticles of a light-absorbing layer.

When a nanocrystal of a metal oxide semiconductor is treated with a combination of a dye and a quantum dot, the region treated only with the dye will generate an electrical current as a result of the interaction of the dye with solar radiation, while the region having the quantum dot light-emitting layer formed thereon displays light-emitting properties as a result of electron-hole recombination.

The solar cell-driven display device can function as a display device using only solar light without needing a separate electric source or a secondary cell, and so provide the effect of reducing maintenance costs when it is applied to an advertising display in isolated areas or in a large-scale advertising board outside buildings.

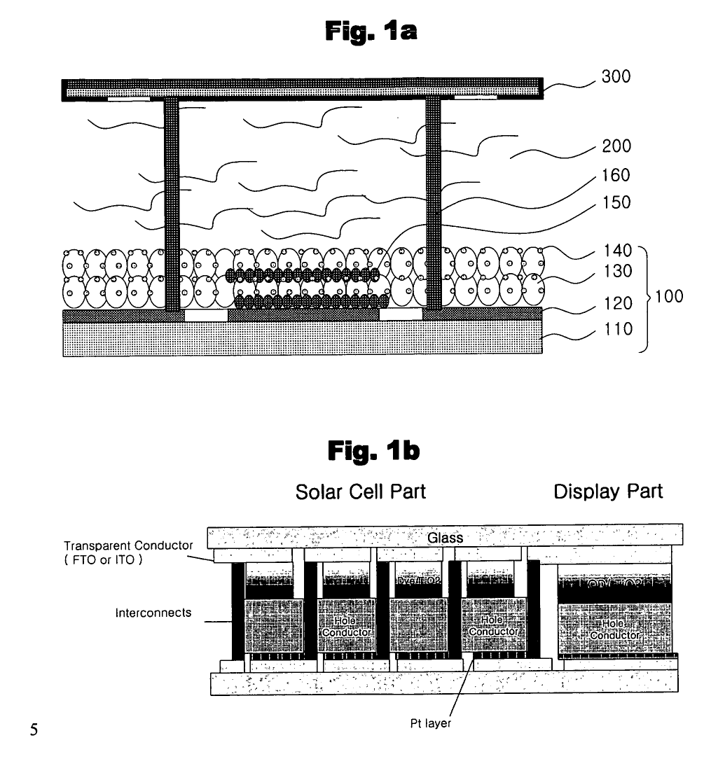

FIG. 1 is a schematic cross-sectional view showing the structure of the solar cell-driven display device according to the present invention. As shown in FIG. 1, the solar cell-driven display device comprises: a transparent electrode 120 that comprises a conductive material coated on a substrate 110; a light-absorbing layer that comprises nanocrystals 130 and dye 140 formed on the transparent electrode; a quantum dot light-emitting layer 150 formed on the surface of the nanocrystals. In one embodiment, the arrangement of the quantum dots may be accomplished in accordance with a desired display pattern. Interconnects 160 serve to connect solar cell unit cells in series with each other and to drive the display section. A counter electrode 300 is disposed opposite the transparent electrode 120; while the hole transport layer 200 is formed in the space between the transparent electrode and the counter electrode.

A quantum dot is a nanosized semiconductor material that shows a quantum confinement effect. This quantum dot will release energy corresponding to the energy band gap thereof, when it absorbs light from an excitation source and reaches an excited energy state. Accordingly, if the size or material composition of the quantum dot is controlled, the energy band gap can be controlled to allow energy of various wavelengths to be used.

In the present invention, a quantum dot usable in the quantum dot light-emitting layer is a compound comprising elements of Groups II and VI, a compound comprising elements of Groups II and V, a compound comprising elements of Groups III and VI, a compound comprising elements of Groups III and V, a compound comprising elements of Groups IV and VI, a compound comprising elements of Groups I, III and VI, a compound comprising elements of Groups II, IV and VI or a compound comprising elements of Groups II, IV and V. Preferred examples of these quantum dot compounds include CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, HgZnSTe, GaNP, GaNAs, GaPAs, AlNP, AlNAs, AlPAs, InNP, InNAs, InPAs, GaAlNP, GaAlNAs, GaAlPAs, GaInNP, GaInNAs, GaInPAs, InAlNP, InAlNAs, InAlPA and a combination comprising at least one of the foregoing compounds.

Moreover, a quantum dot having a core-shell alloy structure may also be used in the present invention. This core-shell alloy quantum dot is a compound semiconductor wherein the core is a compound comprising elements of Group II and VI and the shell is a compound comprising elements of Groups II and VI, a compound comprising elements of Groups II and V, a compound comprising elements of Groups III and VI, a compound comprising elements of Groups III and V, a compound comprising elements of Groups IV and VI, a compound comprising elements of Groups I, III and VI, a compound comprising elements of Groups II, IV and VI, or a compound comprising elements of Groups II, IV and V. For example, the core may be CdSe or CdTe, and the shell may be Zns, ZnSe or CdS.

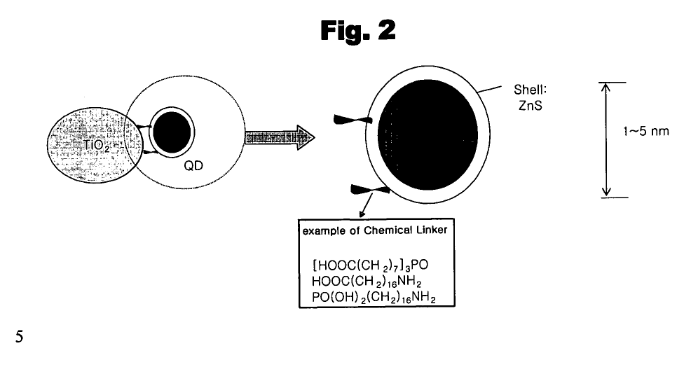

FIG. 2 is a schematic diagram showing a state where a core-shell quantum dot has been linked to the surface of metal oxide. As shown in FIG. 2, the quantum dot component (for example, a structure comprising a core of CdS or CdSe and a shell of ZnS) is linked to the metal oxide semiconductor by a carboxylic acid or phosphoric acid group.

The size of the quantum dot is not specifically limited and is preferably in a range of about 1 to about 10 nanometers (nm). In one embodiment, the size of the quantum dot is about 2 to about 9 nm. In another embodiment, the size of the quantum dot is about 3 to about 7 nm.

Light emission from the quantum dot can be adjusted to a narrow light emission wavelength range by controlling the size and/or composition of the quantum dot. If the quantum dot light-emitting layer consists of quantum dots having uniform particle size distribution, it will emit one color (e.g., white). For light emission, it is required to control the particle size of quantum dots according to desired light-emitting colors. Specifically, quantum dots are screened according to size and patterned according to red-green and blue (RGB) colors.

For example, the particle size of quantum dots for a blue display is in a range of about 1.1 to about 1.5 nm, the particle size of quantum dots for a green display is in a range of about 2.1 to about 2.5 nm, and the particle size of quantum dots for a red display is in a range of about 2.6 to about 3.0 nm.

In the solar cell-driven display device on a portion where patterns such as letters, numerals and symbols, are to be displayed, the quantum dot light-emitting layer is formed of quantum dots having a size conforming to each of the colors to be displayed, and a background portion except for such patterns consists of a solar cell. Thus, the solar cell-driven display device according to the present invention can function both as a solar cell and as a display device.

Quantum dots can be produced through various general methods, including organometallic chemical vapor deposition (OMCVD), chemical beam epitaxy, molecular beam epitaxy (MBE) wet chemical methods, or a combination comprising at least one of the foregoing methods.

Quantum dots using vapor phase deposition methods such as MOCVD (metal organic chemical vapor deposition) or MBE (molecular beam epitaxy) have been attempted. Furthermore, a chemical wet method for growing crystals from a precursor material in an organic solvent has also been developed. The chemical wet method is a method of controlling the growth of crystals by allowing the organic solvent to be naturally coordinated with the quantum dot crystal surface and acts as a dispersing agent. This method has the advantage of being capable of controlling the shape and uniformity of nanocrystals through an easy and inexpensive process when compared with the vapor phase deposition methods such as MOCVD or MBE.

In the solar cell-driven display device, the transparent electrode 120 is formed by coating a conductive material on the substrate 110. The substrate is not limited so long as it is optically transparent. Examples of the substrate which can be used in the present invention include transparent inorganic substrates such as quartz and glass, or transparent plastic substrates such as polymethylmethacrylate (PMMA), polyethylene terephthalate (PET), polyethylene naphathalate (PEN), polycarbonate, polystyrene, polypropylene, or a combination comprising at least one of the foregoing plastic substrates.

The electrically conductive material which is coated on the substrate 110 is exemplified by indium tin oxide (ITO), gallium indium tin oxide, zinc indium tin oxide, titanium nitride, fluorine-doped tin oxide (FTO), ZnO—Ga₂O₃, ZnO—Al₂O₃, SnO₂—Sb₂O₃ or the like, or a combination comprising at least one of the foregoing conductive materials.

In the inventive solar cell-driven display device, the light-absorbing layer consists of a nanocrystalline metal oxide layer 130 and a dye 140 adsorbed on the surface of the metal oxide layer 130. This light-absorbing layer is required to absorb as much light energy as possible in order to obtain high efficiency, and thus the porous metal oxide is used to enlarge the surface of the light-absorbing layer, on which the dye is then adsorbed.

In the present invention, the metal oxide layer 130 can be made of one or more selected from the group consisting of titanium oxide, niobium oxide, hafnium oxide, indium oxide, tin oxide zinc oxide, or the like, or a combination comprising at least one of the foregoing metal oxides. These metal oxides may be used alone or in a mixture of two or more. Preferred examples of the metal oxides may include TiO₂, SnO₂, ZnO, WO₃, Nb₂O₅, and TiSrO₃, and particularly preferable is anatase-type TiO₂.

The metal oxides forming the light-absorbing layer preferably have a large surface area in order to enable the dye adsorbed on the surface to absorb more light and to enhance adhesion to the hole transport layer. Accordingly, the metal oxides of the light-absorbing layer preferably have nanostructures. Examples of such nanostructures are nanotubes, nanowires, nanobelts, nanoparticles Or the like, or a combination comprising at least one of the foregoing nanostructures.

Although there is no particular limitation on the particle size of the metal oxides forming the metal oxide layer 130, the average particle size of primary particles is about 1 to about 200 nm, and preferably about 5 to about 100 nm. It is also possible to use a mixture of at least two metal oxides having different particle sizes to scatter incident light and increase quantum yield.

As the dye 140, which is adsorbed on the metal oxide layer 130, any material can be used as long as it is one generally used in the solar cell field. A ruthenium complex is preferably used. The dye 40 is not specifically limited as long as it has charge separation functions and shows photosensitivity, and examples of the dye 40 may include, in addition to the ruthenium complex, xanthine dyes such as rhodamine B, Rose Bengal, eosin or erythrosine, cyanine dyes such as quanocyanine or cryptocyanine, basic dyes such as phenosafranine, capri blue, thiosine or methylene blue, porphyrin type compounds such as chlorophyll, zinc porphyrin, or magnesium porphyrin, azo dyes, phthalocyanine compounds, complex compounds such as Ru trispyridyl, anthraquinone-base dyes, polycyclic quinone-base dyes, or the like, or a combination comprising at least one of the foregoing dyes. These dyes may be used alone or in a mixture of two or more. Those usable as ruthenium complexes include RuL₂(SCN)₂, RuL₂(H₂O)₂, RuL₃, RuL₂ and the like, wherein L represents 2,2′-bipyridinyl-4,4′-dicarboxylate or the like.

In the inventive solar cell-driven display device, any material may be used to make the opposite electrode 300 as long as it is a conductive material. Even an insulating substance may be used as long as a conductive layer is formed on the side facing the transparent electrode. However, it is preferable to use an electrochemically stable material as the electrode material, and specifically preferable are platinum, gold, carbon, or carbon nanotubes. It is preferably formed along with a transparent electrode layer such as ITO.

Furthermore, to enhance redox catalytic effects, it is preferable for the surface of the counter electrode facing the transparent layer to have a microstructure with an increased surface area. For example, platinum is preferably coated with carbon or carbon black to increase the surface area.

In the present invention, the hole transport layer 200 is preferably made of a solid electrolyte. The solid electrolyte usable herein is not specifically limited, and polypyrrole and derivatives or copolymers thereof may be used. For example, hole transport materials represented by Formulas 1 and 2 below can be used. Also, polythiophene and derivatives or copolymers thereof can be used. For example, the hole transport material represented by Formula 3 below can be used. In addition, the hole transport layer may be made of N,N′-bis(naphthalen-1-yl)-N,N′-bis(phenyl)benzidine (α-NPB), triphenylmethane, carbazole, N,N′-diphenyl-N,N′-bis(3-methylphenyl)-1,1′-biphenyl)-4,4′-diamine (TPD), a spiro or heterospiro hole transport material, tris(aryl methoxyphenyl amino)benzene derivative or the like. 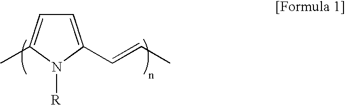
wherein R is a C₁₋₂₀ alkyl group or its derivative, and n is about 10 to about 10000. 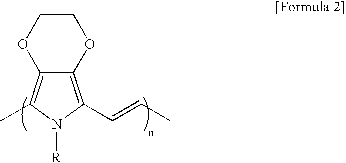
wherein a C₁₋₂₀ alkyl group or its derivative, and n is about 10 to about 10000. 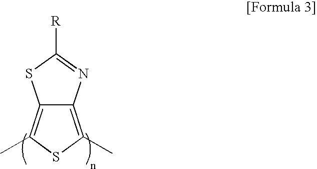
wherein a C₁₋₂₀ alkyl group or its derivative, and n is about 10 to about 10000.

As examples of other hole transport materials, p-type semiconductor materials such as LiI, CuI, CuBr and CuSCN can be added as dopants. Further liquid electrolytes can be added to promote mobility. Compounds such as I₂, acetonitrile, ethylene glycol, propylene carbonate, or the like, or a combination comprising at least one of the foregoing can be added in the form of liquid electrolytes.

The inventive solar cell-driven display can have the desired display properties imparted thereto using a printing method, such as inkjet printing.

The solar cell-driven display device structured as described above operates as follows. The dye 140 adsorbed on the surface of the metal oxide layer 130 absorbs light incident through the counter electrode 300 into the light-absorbing layer. This dye 140 causes the transition of electrons from the ground state to an excited state by absorbing light so as to form electron-hole pairs. Electrons in the excited state are injected into the conduction band of the metal oxide and then migrate to the electrode to generate an electrical current. When the electrons generated by photoexcitation in the dye migrate to the conduction band of the metal oxide, the dye 140 that lost the electrons will receive electrons from the hole transport material of the hole transport layer 200 and return to its original ground state. Meanwhile, regarding the mechanism of light emission in the quantum dot light-emitting layer 150, when electrons and holes are successfully injected into the quantum dots, electron-hole pairs (excitons) are recombined to emit light while releasing photons.

Another aspect of the present invention relates to a method for manufacturing the above-described solar cell-driven display device. To manufacture the solar cell-driven display device, a transparent electrode coated with a conductive material is first prepared and a metal oxide semiconductor layer is then formed on one surface of the transparent electrode.

Although the method for forming the metal oxide layer is not specifically limited, a method of forming the metal oxide layer using a wet process is preferable when considering physical properties, convenience and production costs. A preferable method comprises dispersing metal oxide powder uniformly in a suitable solvent to prepare a paste and coating the paste on a substrate having a transparent conductive film formed thereon. In this case, the coating can be performed using general coating methods, such as spraying, spin coating, dipping, printing, doctor blading, sputtering, electrophoresis, or a combination comprising at least one of the foregoing processes.

After forming the metal oxide layer drying and calcining steps are conducted. The drying step being carried out at about 50 to about 100° C., and the calcining step at about 400 to about 500° C.

The metal oxide layer is then immersed in a solution containing a photosensitive dye for at least 12 hours so as to adsorb the dye on the surface of the metal oxide. The solvent that is used for forming the photosensitive dye-containing solution can be exemplified by tertiary butyl alcohol, acetonitrile, or a mixture thereof. In forming the solar cell-driven display device, it is preferable to use solar cells divided into small units and connected in series with each other, in order to obtain sufficient electric power to produce the quantum dot light-emitting layer.

The quantum dot light-emitting layer comprises quantum dots that are bound with each other to form one layer. The quantum dots can also be bound to the substrate. A quantum dot light-emitting layer having a core-shell alloy structure as shown in FIG. 2 is suitable for the purpose of the present invention, and compounds such as CdSe—ZnS and CdS—ZnS are easily prepared and offer easy processability. In order to adsorb the quantum dot light-emitting layer onto the nanocrystalline semiconductor metal oxide by a self-assembly method, chemical linkers such as organic amine compounds or organic phosphine oxide compounds, which contain carboxylic acid or phosphoric acid, are formed on the quantum dot light-emitting layer.

In forming the quantum dot oxide layer, the quantum dot light-emitting material is adsorbed on a portion of the surface of the nanocrystalline semiconductor material in a geometry that correlates with the pattern to be displayed. Specifically, a dispersion containing quantum dots is applied on the metal oxide adsorbed with the dye, using methods such as inkjet printing, screen printing, spraying, drop casting, electrophoresis, or the like, or a combination comprising at least one of the foregoing methods. Examples of a solvent useful in this application step include water, alcohols such as ethanol or propanol, ketone compounds such as acetone or 2-butanone, and acetate compounds, or the like, or a combination comprising at least one of the foregoing solvents.

In the present invention, the method of forming the hole transport layer can be performed using any method capable of increasing the adhesion of the hole transport layer to the metal oxide of the metal oxide layer or the counter electrode. Examples of this method may include spin coating, dipping, spraying, roll coating, blade coating, gravure coating, screen printing, doctor blading, or the like, or a combination comprising at least one of the foregoing processes.

Hereinafter, the present invention will be described in more detail by an example.

### EXAMPLE

As shown in FIG. 1, fluorine-doped tin oxide (FTO) was deposited as a transparent electrode layer on a glass substrate. The electrode layer was etched to form patterns having a desired geometry. Then, on the FTO film, a paste of TiO₂ (average size: 12 nm; commercially available under the trade name of Ti-nanoxide HTSP from Solaronix SA) was screen-printed, and calcined at 500° C. for 30 minutes to form a 12 micrometer (μm) thick semiconductor layer. Next, the resulting substrate was dipped in 0.3 millimolar (mM) ruthenium dithiocyanate 2,2′-bipyridyl-4,4′-dicarboxylate solution for 12 hours and dried so as to adsorb the dye on the surface of the TiO₂ layer.

A quantum dot compound having a particle size distribution of about 3 to about 5 nm and a core-shell structure of CdSe—ZnS was surface-treated with tri-(1-carboxy)heptylphosphine oxide and then dispersed in an alcohol solution. The quantum dot light-emitting layer solution was printed on a display portion and dried at 50° C.

Then, N,N′-bis(napthalen-1-yl)-N,N′-bis(phenyl)benzidine (α-NPB) was formed on the resulting structure by thermal deposition while keeping away from portions to be interconnected. Interconnects between solar cell units were printed with silver paste to form patterns connected in series, and a counter electrode having a platinum layer and FTO transparent conductive film formed thereon was then formed on the resulting structure, thus manufacturing a solar cell-driven light-emitting display device as shown in FIG. 1b. When six solar cell units were connected in series with each other, these could produce electric powers of 4 volt (V) and 15 milliamperes (mA) upon irradiation with solar light of 100 milliwatt per square centimeter (mW/cm²), indicating that light emission by quantum dots was possible.

Although the inventive display device can be used as, for example, an advertising display in isolated areas or outside buildings as described above, it may also be advantageously used as a display element for various portable devices, including notebook computers, e-books, personal digital assistants (PDA) and hand-held phones.

The solar cell-driven display device according to the present invention can function as a display device using only solar light without needing a separate power supply device, so that it can be used as an advertising display in isolated areas or other outdoor advertising displays, in which case it can provide the effect of reducing maintenance costs.

Furthermore, the solar cell-driven display device according to the present invention can combine the function of a display device by using the fundamental elements of the dye-sensitized solar cell, and thus can be manufactured via an inexpensive and relatively simple process.

In addition, the solar cell-driven display device according to the present invention can function both as a display device and as a solar cell and can be manufactured at low costs in a simple manner without complex interconnection and circuit processes.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A solar cell-driven display device comprising:
a light-absorbing layer comprising a semiconductor electrode that comprises a transparent electrode formed on a substrate and nanocrystals formed on the transparent electrode and adsorbed with a photosensitive dye;
a hole transport layer;
a counter electrode; and
a quantum dot light-emitting layer formed on the surfaces of nanocrystals of the light-absorbing layer.

2. The solar cell-driven display device of claim 1 which comprises:
a transparent electrode comprising a conductive material coated on a substrate;
a light-absorbing layer comprising nanocrystals adsorbed with a photosensitive dye on the transparent electrode;
a quantum dot-light emitting layer formed on the surface of the light-absorbing layer having a geometry of a desired display pattern;
a counter electrode disposed opposite the transparent electrode; and
a hole transport layer formed in the space between the transparent electrode and the counter electrode.

3. The solar cell-driven display device of claim 1, wherein the quantum dot light-emitting layer shows display characteristics due to electricity generated by the solar cell.

4. The solar cell-driven display device of claim 1, wherein the quantum dot is selected from the group consisting of compounds comprising elements of Groups II and VI, compounds comprising elements of Groups II and V, compounds comprising elements of Groups III and VI, compounds comprising elements of Groups III and V, compounds comprising elements of Groups IV and VI, compounds comprising elements of Groups I, III, and VI, compounds comprising elements of Groups II, IV, and VI, compounds comprising elements of Groups II, IV, and V, and a combination comprising at least one of the foregoing compounds.

5. The solar cell-driven display device of claim 4, wherein the quantum dot compound is selected from among a group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, HgZnSTe, GaNP, GaNAs, GaPAs, AlNP, AlNAs, AlPAs, InNP, InNAs, InPAs, GaAlNP, GaAlNAs, GaAlPAs, GaInNP, GaInNAs, GaInPAs, InAlNP, InAlNAs, InAlPAs, and a combination comprising at least one of the foregoing compounds.

6. The solar cell-driven display device of claim 1, wherein the quantum dot is a quantum dot having a core-shell alloy structure wherein the core comprises a compound comprising elements of Groups II and VI and the shell comprises a compound comprising elements of Groups II and VI, elements of Groups II and V, elements of Groups III and VI, elements of Groups III and V, elements of Groups IV and VI, elements of Groups I, III, and VI, elements of Groups II, IV, and VI, elements of Groups II, IV, and V or a combination comprising at least one of the foregoing compounds.

7. The solar cell-driven display device of claim 2, wherein the hole transport layer is made of a solid electrolyte.

8. The polar cell driven display device of claim 7, wherein the solid electrolyte is selected from polypyrrole or derivatives or copolymers thereof, including hole transport materials represented by Formulas 1 and 2, polythiophene and derivatives or copolymers thereof, including a hole transport material represented by Formula 3, N,N′-bis(naphthalen-1-yl)-N,N′-bis(phenyl)benzidine, triphenylmethane, carbazole, N,N′-diphenyl-N,N′-bis(3-methylphenyl)-1,1′-biphenyl)-4,4′-diamine spiro or heterospiro hole transport materials, and tris(aryl methoxyphenyl amino) benzene derivatives: 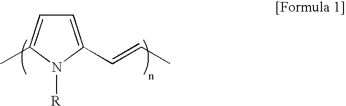
wherein R is a C₁₋₂₀ alkyl group or a derivative thereof, and n is about 10 to about 10,000; 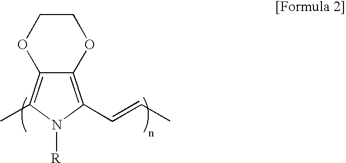
wherein R is a C₁₋₂₀ alkyl group or a derivative thereof, and n is about 10 to about 10,000; and 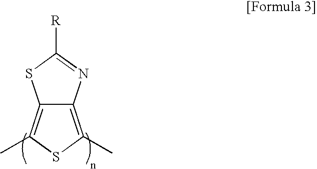
wherein R is a C₁₋₂₀ alkyl group or a derivative thereof, and n is about 10 to about 10,000.

9. The solar cell-driven display device of claim 3, wherein the metal oxide layer is formed of a material selected from the group consisting of TiO₂, ZnO, Nb₂O₅, WO₃, SnO₂ MgO, and a combination comprising at least one of the foregoing materials.

10. A method for manufacturing a solar cell-driven display device, comprising, after forming a light-absorbing layer, forming a quantum dot light-emitting layer on a metal oxide of the light-absorbing layer having a geometry in accordance with a desired display pattern.

11. The method of claim 10, which comprises the steps of:
forming on a transparent electrode a layer comprising a nanocrystalline semiconductor material and a dye molecule adsorbed on a portion of the nanocrystalline material;
adsorbing a quantum dot light-emitting material on a surface of the nanocrystalline semiconductor material according to patterns to be displayed, thus forming a quantum dot light-emitting layer;
forming a hole transport layer on the nanocrystalline semiconductor layer on which the dye molecule and the quantum dot light-emitting layer have been adsorbed; and
forming a counter electrode on the hole transport layer.

12. The method of claim 11, wherein the step of forming the quantum dot light-emitting layer is performed by dispersing quantum dots screened according to size in a solvent and forming the dispersion into patterns by inkjet printing, screen printing, spraying, electrophoresis, or a combination comprising at least one of the foregoing methods.
